(19) United States
(12) Patent Application Publication
(10) Pub. No.: US 2017/0005212 A1
(43) Pub. Date: Jan. 5, 2017

(54) SOLAR CELL WITH OPTIMIZED LOCAL REAR-CONTACTS

(71) Applicant: SolarWorld Innovations GmbH, Freiberg (DE)

(72) Inventors: Matthias Mueller, Freiberg (DE); Stefan Steckemetz, Freiberg (DE); Bernd Bitnar, Bannewitz (DE); Roman Schiepe, Dresden (DE)

(21) Appl. No.: 15/153,774

(22) Filed: May 13, 2016

(30) Foreign Application Priority Data
Jul. 3, 2015 (DE) 20 2015 103 518.7

(51) Int. Cl. H01L 31/0224; H01L 31/18; H01L 31/0236; H01L 31/028; H01L 31/0216

(52) U.S. Cl. CPC H01L 31/022441; H01L 31/028; H01L 31/02168; H01L 31/02363; H01L 31/1804

(57) ABSTRACT

A solar cell includes a silicon substrate with a front-side and a rear-side; a dielectric layer structure on the rear-side of the silicon substrate, wherein the dielectric layer structure includes a plurality of through openings by means of which the rear-side of the silicon substrate is exposed; a printed Aluminum-containing metallization layer on the dielectric layer structure on the rear-side of the silicon substrate and at least partially in the through openings for electrically contacting the rear-side of the silicon substrate; wherein the Aluminum-containing metallization includes a lower layer thickness in a first area than in a second area, or the first area is free from the Aluminum-containing metallization; wherein at least one through opening of the plurality of through openings is at least partially disposed in the first area or borders on the first area or has a distance from the first area of less than 500 μm.

### CROSS-REFERENCE TO RELATED APPLICATION

This application claims priority to German Utility Model Application Serial No. 20 2015 103 518.7, which was filed Jul. 3, 2015, and is incorporated herein by reference in its entirety.

### TECHNICAL FIELD

Various embodiments relate generally to a solar cell with optimized local rear-contacts.

### BACKGROUND

Solar cells are components, which directly convert electromagnetic radiation, particularly sunlight into electric energy. For example, they are used to generate energy in power plants and in space travel.

A solar cell can include a substrate, e.g. a Silicon substrate having a front-side (also referred to as Sun-side or Light-incident side) which receives light, and a rear-side.

Conventional solar cells include a rear-side contact (also referred to as metallization layer in the following) on the rear-side thereof, which can be made for example by means of printing, for example screen-printing of an Aluminum paste (“Al-Paste”) on the rear-side of the solar cell. During the screen-printing, Al-Paste is pressed, for example through a finely woven fabric by means of a so-called scraper and thus an Aluminum-containing metallization layer is produced.

In a manufacturing process of a solar cell, such a metallization layer is subjected to changes. Depending on the viscosity of the Al-paste, generally the design of the screen (“screen layout”) does not identically corresponds to the print-image of the Al-paste on the rear-side of the solar cell.

Normally, in a so-called PERC-solar cell (passivated emitter and rear cell, passivated Emitter- and rear-side cell), which includes a Silicon substrate, a dielectric layer structure is applied on the rear-side of the PERC solar cell. Generally, the dielectric layer structure is used for reducing the charge-carrier combination (“Passivation”) on the rear-side surface of the Silicon substrate. A PERC-solar cell generally achieves a higher efficiency by means of this passivation than for example a conventional Al-BSF-solar cell (BSF: back surface field, rear-side surface field), which includes no dielectric layer structure on the rear-side of the solar cell.

In a conventional PERC-solar cell, the through openings extend through the dielectric layer structure, which partially expose Silicon substrate. For example, these through openings can be introduced by means of a Laser process (for example, in different shapes of—for example—circles, continuous or regular interrupted lines) in the dielectric layer structure, as described in DE102013111634 A1. An Aluminum-containing metallization layer is shaped flat by means of screen-printing of an Al-Paste on the dielectric layer structure and in the through openings. For example, only contact areas, on which the solar cells need to be soldered later, can be printed instead of or in addition to a Silver-Paste (“Ag-Paste”) that can be soldered.

The region of a through opening means the volume of the metallization layer (or printed, dried and molten also), which directly is applied on the through opening. For example, if a through opening has a circular base area, the region of the through opening would be a cylinder with the same circular base area and with the height of the layer thickness (in case of a homogeneous layer thickness) of the metallization layer, which is directly applied on the through opening.

After the screen-printing and the drying process, the Aluminum particle in the Al-Paste is molten in a subsequent heat-treatment (the so-called “Firing process” or “firing” or also “co-firing” in the range of temperature of about 700° C.-900° C.). The molten Aluminum releases Silicon from the Silicon substrate in the areas, in which Silicon substrate has direct contact with the molten Aluminum-containing metallization layer by means of the introduced through openings. The molten Aluminum along with the released Silicon forms a liquid phase, the Aluminum-Silicon melt. This is enriched with Si during the “Firing process” and exceeds a Si mass-ratio of 12.5% by weight, so that a BSF can be formed on the interface of Silicon substrate with the Al—Si melt while cooling down. The volume of Al—Si melt is dependent on the volume of the available molten Aluminum, in which the released Silicon can diffuse out. Since the released Silicon can also diffuse out in the surrounding Aluminum outside the region of a respective through opening, a large-scale Al/Si melt can be formed.

In a subsequent cooling phase after the firing process, Silicon released from Al/Si melt recrystallizes on Silicon substrate in the through openings. During the recrystallization of the previously released Silicon, Aluminum is attached in the crystal grid thereof. Since Aluminum can function as dopant in Silicon, a so-called Al-BSF (Aluminum Back-Surface-Field, Aluminum rear-side field) is formed by means of the recrystallized Silicon with attached Aluminum. If the temperature drops below 577° C., finally the melt solidifies with a Si to Al—Si eutectic mass-ratio of 12.5% by weight.

During the firing process, the released Silicon may diffuse out of the regions of the through openings into the molten Aluminum of the molten Aluminum-containing metallization layer. As a result, the concentration of released Silicon reduces in the regions of the through openings. This may result in that there is too low Silicon available for forming a suitable Al-BSF during the recrystallization of the released Silicon in the cooling phase in the surroundings of the through openings. For example, partially no Al-BSF or only an Al-BSF with a smaller thickness (i.e. for example below 1 μm) can form. In a smaller thickness or a lack of Al-BSF, the charge carrier combination in the solar cell is enhanced and the efficiency of the solar cell is restricted thereby.

### SUMMARY

A solar cell includes a silicon substrate with a front-side and a rear-side; a dielectric layer structure on the rear-side of the silicon substrate, wherein the dielectric layer structure includes a plurality of through openings by means of which the rear-side of the silicon substrate is exposed; a printed Aluminum-containing metallization layer on the dielectric layer structure on the rear-side of the silicon substrate and at least partially in the through openings for electrically contacting the rear-side of the silicon substrate; wherein the Aluminum-containing metallization includes a lower layer thickness in a first area than in a second area, or the first area is free from the Aluminum-containing metallization; wherein at least one through opening of the plurality of through openings is at least partially disposed in the first area or borders on the first area or has a distance from the first area of less than 500 μm.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1C show a top-view at a section of a solar cell module having a plurality of solar cells according to various embodiments (FIG. 1A), a cross-sectional view of a solar cell of the solar cell module from FIG. 1A (FIG. 1B) and an enlarged view of a partial area of the solar cell (FIG. 1C) represented in FIG. 1B;

FIGS. 2A to 2L show different configurations of the metallization layer in the cross-section;

FIGS. 3A to 3D show different configurations of the metallization layer in top-view;

FIG. 4A shows a screen layout for the screen-printing of a metallization layer;

FIG. 4B shows a configuration of the metallization layer in top-view;

FIGS. 5A to 5C show different configurations of the metallization layer in top-view; and

FIG. 6 shows an embodiment of a process for manufacturing a solar cell.

### DESCRIPTION

The following detailed description refers to the accompanying drawings that show, by way of illustration, specific details and embodiments in which the invention may be practiced.

In the following detailed description, reference is made to the accompanying drawings, which form part of this and in which specific exemplary embodiments are shown for illustration, in which the invention can be exercised. In this respect, the directional terminology such as “above”, “below/under”, “in front”, “behind”, “forward”, “rearward”, etc. are used with reference to the orientation of the described figure(s). Since components of exemplary embodiments can be positioned in a number of different orientations, the directional terminology is used only for illustration and is not limiting in any way. It should be noted that other embodiments can be used and structural or logical modifications can be undertaken without departing from the scope of protection of the present invention. It should be noted that the features of the various embodiments described herein, can be combined with each other, unless not specifically stated otherwise. Therefore, the following detailed description should not to be understood in a restrictive sense, and the scope of protection of the present invention is defined by the accompanying claims.

Within the scope of this description, the terms “joined”, “connected” and “coupled” are used for describing a direct as well as an indirect joint, a direct or indirect connection and a direct or indirect coupling. In the figures, identical or similar elements are provided with identical reference numerals, where appropriate.

In various embodiments, a solar cell is provided with a rear-side Aluminum-containing metallization layer, wherein the concentration of released Silicon in the Aluminum-containing metallization layer is or will be locally increased during a firing process.

The local increase of Silicon concentration affects the homogeneity and the thickness of Al-BSF.

In various embodiments, a solar cell is provided which includes: a Silicon substrate having a front-side and a rear-side; a dielectric layer structure on the rear-side of Silicon substrate, wherein the dielectric layer structure includes a plurality of through openings, by means of which the rear-side of Silicon substrate is exposed; a printed Aluminum-containing metallization layer on the dielectric layer structure on the rear-side of Silicon substrate and at least partially in the through openings for electrically contacting the rear-side of Silicon substrate; wherein the Aluminum-containing metallization layer in a first area has a smaller layer thickness than in a second area, or the first area is free from the Aluminum-containing metallization layer; wherein at least one through opening of the plurality of through openings is at least partially disposed in the first area or borders the first area or has a distance from the first area of less than 500 μm, e.g. less than 200 μm, e.g. less than 50 μm.

A printed metallization layer can mean a metallization layer after completing the printing process, for example after completing the screen-printing or Inkjet printing. A dry metallization layer can mean the printed metallization layer after completing the drying process (for example, a heat-treatment at about 300° C.). A molten metallization layer can mean the dried metallization layer, which is at least partially molten during the firing process described below.

A dielectric layer structure can include a single layer or a stack of layers with a plurality of layers, for example of Silicon nitride and/or Silicon oxide and/or Aluminum oxide and/or Silicon carbide or a combination thereof. The dielectric layer structure can perform a plurality of functions. For a PERC-solar cell, it can constitute—for example—a mask by means of which an Aluminum-containing metallization layer (or printed, dried and molten also) is not (or provided only in areas such as through openings) in direct contact with the Silicon substrate. Moreover, such a dielectric layer structure can passivate the surface of the Silicon substrate. This means that the recombination of charge carriers is reduced. Moreover, the dielectric layer structure can, by means of suitable selection of the optical refractive index/indices of the material used, have the function of a dielectric mirror. For example, there is a probability that infrared light (for example, in the range of wavelengths of approximately 950 to approximately 1150 nm), which penetrates through the front-side of the solar cell, generates no charge carrier pair in a first passage through the Silicon substrate. By means of a dielectric mirror on the rear-side of the Silicon substrate, this infrared light can be reflected and so a second passage through the Silicon substrate and thus, an increased probability of generating the charge carrier pair may be enabled. The dielectric layer structure, which partially insulates the Aluminum-containing metallization layer (or printed, dried and molten also) from the Silicon substrate, can be electrically insulated. However, even electrically conductive layers can be added to the dielectric layer structure, so that the overall electrical resistance of the solar cell can be affected.

The through openings in the dielectric layer structure, which expose the Silicon substrate, enable the Aluminum-containing metallization layer (or printed, dried and molten also) to directly contact the Silicon substrate.

The dielectric layer structure can have a layer thickness in the nanometer range (for example smaller than 200 nm) and the Aluminum-containing metallization layer can have a layer thickness in micrometer range (for example in the range of approximately 10 μm to approximately 100 μm) before as well as after the firing process. Further, an Al-paste used in various embodiments can have—for example, organic materials, which keep the Al-paste liquid. This viscosity of the Al-paste can smooth out the unevenness during the screen-printing. Areas of the dielectric layer structure with and without a through opening, on which an Al-paste is pressed, cannot be practically distinguished in top-view on the Aluminum-containing metallization layer.

The Al-paste can be dried after the screen-printing of the Al-paste. Therefore, the organic materials can be partially destroyed and/or diffused out. In a firing process described above, an Al-BSF is formed in the through openings of the dielectric layer structure, in which the molten metallization layer is in direct contact with the Silicon substrate. Inter alia, this Al-BSF has the effect that an electrical contact with a lower electrical resistance is made between the Aluminum-containing metallization layer and the Silicon substrate. Since Aluminum works as a dopant in Silicon, the Al-BSF also reduces the charge carrier combination. This occurs, for example electrons are “reflected” depending on the additional doping in the Al-BSF and thus, does not reach the rear-side of the Silicon substrate, where an increased possibility of charge carrier recombination prevails.

The generation of Al-BSF by means of Silicon, which is released from the Silicon substrate during the firing process, can affect the geometric shape of Al-BSF and of the electrical contacts formed thereby. So, for example in a circular through opening, Silicon can be released from the Silicon substrate in an approximately hemispherical shape. After cooling down, the Al-BSF can be laid as a layer on the position of the surface of the hemisphere and Aluminum of the metallization can at least partially fill out the volume of the hemisphere. Since such a geometric shape highly depends on several parameters, for example the composition of the Al-Paste, the temperatures in the firing process and the geometric shapes of the through openings, the Al-BSF is generally marked below as rectangle in the following schematic drawings without limiting the generality.

A first area, which includes an Aluminum-containing metallization layer of smaller layer thickness as a second area or includes no Aluminum-containing metallization layer, can affect the diffusion of Silicon released during the firing process out of the region of the through opening into the surrounding molten Aluminum. By means of limiting the volume of molten Aluminum in which released Silicon can diffuse, the concentration of released Silicon in the region of the through opening can be increased. Thus, more Silicon is available in the region of the through opening for forming Al-BSF during the recrystallization.

In addition, an additional material can be introduced in the first area and/or the partial areas thereof. For example, an electrically insulating paste can be introduced by means of screen-printing. The introduced additional material is used as a barrier for the diffusion of the Silicon released during the firing process. The introduced additional material can stabilize the geometrical shape of a first area and/or partial areas thereof, particularly during the firing process. The introduced additional material can also be electrically conductive and can electrically interconnect different first and/or second areas or partial areas of the metallization layer.

The introduced material can also include for example, a so-called oblation paste, which is decomposed in the firing process and leaves behind the first area or the partial areas thereof with reduced layer thickness of the metallization layer.

In the second area, the Aluminum-containing metallization layer can have a homogeneous layer thickness, as developed by means of screen-printing of Al-Paste (for example between 10 μm and 100 μm). The layer thickness can be optimized such that, a highest possible electrical conductivity of the metallization layer is provided with minimum use of Al-Paste (cost saving).

In a top-view on the rear-side of the solar cell, the distance is indicated as the shortest distance between two peripheral points of two directly adjacent through openings.

According to an embodiment, the at least one through opening of the plurality of through openings can be configured in the shape of an elongated trench.

According to an embodiment, the at least one through opening of the plurality of through openings can have a length, which is greater than the width thereof, thus can also be rectangular or elliptical, wherein at least one end area of the at least one through opening is disposed in the first area or borders on the first area or has a distance of less than 500 μm, e.g. less than 200 μm, e.g. less than 50 μm from the first area.

According to an embodiment, the at least one through opening of the plurality of through openings can have a length, which is greater than or equal to the width thereof, thus can also be rectangular or elliptical, wherein at least one end area of the at least one through opening is disposed in the first area or borders on the first area or has a distance of less than 500 μm, e.g. less than 200 μm, particularly less than 50 μm from the first area.

According to an embodiment, the at least one through opening of the plurality of through openings can be configured in the shape of a prism or a circular cylinder. Therefore, it can involve a prism with a regular rectangle as base surface.

According to the number, distribution and geometrical dimension of the through openings, the dimensions of the surface of the Silicon substrate can be optimized with passivation on the one side and the overall electrical resistance on the other side by means of the geometrical dimensions of the electrical contact between Silicon substrate and metallization layer.

According to another embodiment, both end areas of the at least one through opening can be disposed in the first area or can border on the first area or have a distance of less than 500 μm, e.g. less than 200 μm, e.g. less than 50 μm from the first area.

For example, in through openings in the shape of elongated trenches, experimentally an increased possibility can be observed that Al-BSF is not configured or configured with too small thickness in the end areas of the trenches. This is related to the fact that a three-dimensional Aluminum volume is available on both the end areas of a trench, in which the released Silicon can diffuse out during the firing process. By means of a first area or a plurality of first partial areas, the formation of Al-BSF can be improved in the end areas of the trenches.

According to various embodiments, a solar cell can include a first area, wherein this has a plurality of first partial areas; and the solar cell can have a second area, wherein this includes a plurality of second partial areas. Each second partial area can be configured at least partially in at least one through opening for electrically contacting the rear-side of the Silicon substrate. Each of the second partial areas can be disposed at least partially in a first partial area of the plurality of first partial areas.

Because of the division of the first area in first partial areas and the second area in a plurality of second partial areas, for example a second partial area can be fully surrounded by means of a first partial area. Thus, there is a barrier for the diffusion of Silicon released during the firing process in all direction in the molten metallization layer. In order to ensure the electrical contact between the Al-BSF formed and the metallization layer on the entire rear-side of the solar cell, the first area or the partial area thereof as described above, can have a reduced layer thickness.

Alternatively, it is also possible to configure the first area or partial areas thereof without metallization layer. In this case, a small geometric dimension of the first area, or partial areas thereof can be used. During the firing process, the at least partially molten Aluminum-containing metallization layer of the second area or partial areas thereof penetrates into the first area or partial areas thereof. Thus, an electrical contact can be made between different areas and partial areas.

Furthermore, the second partial areas can be configured substantially in strip shape.

By means of strip-shaped second partial areas, a plurality of electrical contacts formed in the through openings by means of Al-BSF can be electrically interconnected. An electrical connection of a plurality of strip-shaped second partial areas can also be produced by means of one or more additional strip-shaped second partial areas, which can be attached at an angle (for example perpendicular) to the strip-shaped second partial areas. The electrical contacting of the solar cell can be carried out for example by means of the additional strip-shaped second partial areas (and/or solder pads in contact therewith).

Further, the second partial areas can be wider at least in a partial area of the through openings than outside the at least one partial area of the through openings.

Further, the layer thickness of the Aluminum-containing metallization layer cannot be constant in the first area.

By means of non-constant layer thicknesses of the metallization layer in the first area or partial areas thereof, the volume of the molten Aluminum can be optimized for the diffusion of the Silicon released during the firing process. The non-constant layer thicknesses in the first area or partial areas thereof can for example increase or decrease or take other shapes. The shapes affect the electrical conductivity of the metallization layer.

The dielectric layer structure can also include one or more layers, wherein at least one of the plurality of layers is a dielectric layer. Dielectric layer structures are described above in more details.

A solar cell according to various embodiments can be electrically connected to further solar cells and can be embedded in a solar cell module.

The Silicon substrate can have a length of 156 mm, a width of 156 mm and a height of 200 μm. On the rear-side of the solar cell, the Silicon substrate can be in direct contact with the dielectric layer structure, which is on the entire rear-side. The dielectric layer structure can consist of or include electrically insulating Silicon nitride or one such and can have a layer thickness in the range of approximately 20 nm to approximately 200 nm, for example approximately 70 nm to approximately 170 nm. In the dielectric layer structure, a plurality of through openings can be disposed in the shape of circles with a radius of approximately 20 μm and expose the Silicon substrate. The positioning of the plurality of through openings in the dielectric layer structure can be distributed homogeneously over the area of the dielectric layer structure. The through openings expose for example about 10% of Silicon substrates. An Aluminum-containing metallization layer (homogeneous layer thickness of approximately 25 μm) is completely (except in the first areas) disposed on the dielectric layer by means of screen-printing of an Al-Paste. The first areas of the metallization layer can be configured circular, wherein the radius can be 20 μm. The layer thickness of the metallization layer in the first areas is for example approximately 10 μm. The first areas are disposed for example centered on each of the through opening. The through openings enable an electrical contact between the metallization layer and the Silicon substrate. Depending on a firing process, an Al-BSF is located between the Aluminum-containing metallization layer and the Silicon substrate.

A method for manufacturing a solar cell is provided in various embodiments. The method can include forming a dielectric layer structure with a plurality of through openings on the rear-side of a Silicon substrate, wherein the rear-side of the Silicon substrate is partially exposed by means of the through openings; and printing an Aluminum-containing metallization layer on the dielectric layer structure and at least partially in the through openings for electrically contacting the rear-side of the Silicon substrate. In a first area, the Aluminum-containing metallization layer has a smaller layer thickness than in a second area. Alternatively, the first area is free from the Aluminum-containing metallization layer. At least one through opening of the plurality of through openings is disposed at least partially in the first area, or borders on the first area or is disposed at a distance of less than 500 μm, e.g. less than 200 μm, e.g. less than 50 μm from the first area.

The dielectric layer structure, which is applied on the rear-side of the Silicon substrate, can be formed, for example by means of one or more deposition processes (for example one or more deposition processes out of Gas phase (PECVD, CVD) or one or more physical deposition processes (for example sputtering)). A dielectric layer structure can be used as a reservoir for, for example hydrogen. This hydrogen can reach the surface and in the Silicon substrate in a heat treatment, such as firing process. The hydrogen can passivate the defects, such as foreign atoms in the Silicon or crystal lattice defects (which also include the surface of the Silicon substrate), i.e. lower the probability of a recombination of charge carriers.

The through openings can be produced for example because a dielectric layer structure is formed on the rear-side of the Silicon substrate and the through openings are produced by means of Laser- and/or etching processes (for example Laser ablation or screen-printing of an etching paste) in the dielectric layer structure. Alternatively, a dielectric layer structure can be formed because the dielectric layer structure is applied only partially by means of a masking of the rear-side of the Silicon substrate.

The Aluminum-containing metallization layer can form with the Silicon substrate as described above, an Al-BSF and thereby an electrical contact with low electrical resistance. A so-called “gettering” can take place during the firing process. During the firing process, impurities of Silicon substrate are more mobile due to the increased temperature in the Silicon substrate. This mobile impurities can diffuse out of the Silicon substrate into the Al/Si eutectic and the molten Aluminum. The reduction in the concentration of impurities in the Silicon substrate can lower the recombination probability of charge carriers in the Silicon substrate.

The viscosity of Al-paste can be used during the screen-printing. For example, by means of a screen-layout which provides only the screen-printing of a metallization layer in a partial area of a through opening, Al-paste reach the entire through opening during the screen-printing.

The first area of the metallization layer can be produced for example as a result of a flat uniform metallization layer printed by screen-printing on the dielectric layer structure and is applied on the through openings. Subsequently, (wherein Al-paste can be more liquid or dried) the layer thickness of the printed metallization layer can be locally reduced or the printed metallization layer can be fully removed by means of a Laser process (for example Laser ablation) or a mechanical process (for example by means of stamping).

Alternatively, a first area is produced during the screen-printing of the Al-paste, for example by means of the corresponding selection or design of the screen. For example, a screen can be sealed at the locations on which a first area is realized, by a coating, e.g. an emulsion layer, so that no Al-paste can be locally pressed on the dielectric layer on these locations. Alternatively, for example the geometric shape of the stitches in the finely woven fabric of the screen can be changed, so that on these locations, less Al-paste is pressed locally. It is also possible to configure the scraper such that for example by means of decomposition in individually controllable parts, wherever a first area can be locally produced; that less or no pressure is locally applied on the screen by means of the scraper and thereby less or no Al-paste is locally pressed through the screen.

According to various embodiments, the at least one through opening of the plurality of through openings can be configured in the shape of an elongated trench.

According to various embodiments, the at least one through opening of the plurality of through openings can have a length, which is greater than or equal to the width thereof, thus can also be rectangular or elliptical, wherein at least one end area of the at least through opening is disposed in the first area or borders on the first area or has a distance of less than 500 μm, e.g. less than 200 μm, e.g. less than 50 μm from the first area.

According to various embodiments, both end areas of the at least one through opening can be disposed in the first area or can border on the first area or have a distance of less than approximately less than 500 μm, for example less than approximately 200 μm, for example less than approximately 50 μm.

Furthermore, the first area can include a plurality of first partial areas; and the second area can include a plurality of second partial areas; wherein each of the second partial areas is configured at least partially in at least one through opening for electrically contacting the rear-side of the Silicon substrate; and wherein each of the second partial areas is at least partially disposed in a first partial area of the plurality of first partial areas.

During the firing process, molten Aluminum of the metallization layer can penetrate into a first area or partial areas thereof. This process requires a certain duration. During this time, a first area or partial areas thereof constitute an barrier for the diffusion of the released Silicon. Thus, the concentration of Silicon released in the region of the through opening can be increased during the firing process. After the firing process, depending on the penetration of Aluminum in the first area or partial areas thereof, the electrical conductivity of the first area or partial areas thereof can be increased. So that, second partial areas which were electrically insulated from each other by means of screen-printing, can be electrically connected after a firing process.

Further, the second partial areas can be configured substantially strip-shaped.

The second partial areas can be configured, at least in a partial area of the through openings, wider than outside the at least one partial area of the through openings.

Various embodiments, which involve different resulting geometries of the metallization layer (or first areas, second areas, first partial areas and second partial areas), can be realized by the above described method.

According to various embodiments, the layer thickness of the metallization layer in the first area cannot be configured constant.

A non-constant layer thickness of the metallization layer in the first area or partial areas thereof can be produced in various ways. A Laser process (e.g. Laser ablation) can be used for example. Alternatively, as described above, the layer thickness can be affected by means of the design of the screen in the screen-printing. Alternatively, a corresponding pattern can be engraved by means of a corresponding mechanical stamping in a printed metallization layer.

According to another exemplary method, the dielectric layer structure can be configured with one or more layers, wherein at least one of the plurality of layers is a dielectric layer.

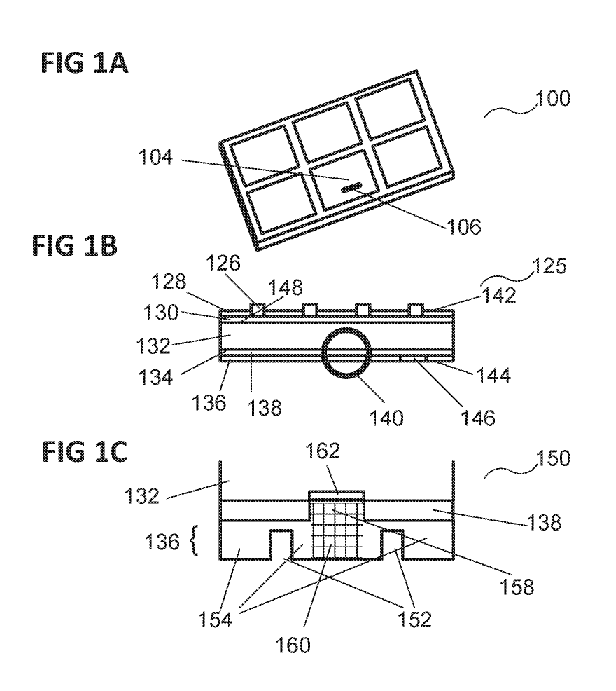

FIG. 1A schematically shows a top-view at a section of a solar cell module 100 having a plurality of solar cells 104. FIG. 1B shows a sectional-view 125 of a solar cell 104 from FIG. 1A and FIG. 1C shows an enlarged view 150 of a partial area of the solar cell 104 from FIG. 1A represented in FIG. 1B.

The solar cell module 100 includes several electrically interconnected (in series or parallel) solar cells 104. A marking 106 indicates the position of the cross-section, which is shown in the enlarged cross-sectional view 125 in FIG. 1B.

A cross-section of the solar cell 104 is shown in the enlarged cross-sectional view 125 of the solar cell module 100. The solar cell 104 has a front-side 142 and a rear-side 144. The solar cell 104 includes a Silicon substrate 132 (for example monocrystalline, alternatively quasi-monocrystalline, polycrystalline or even amorphous) having a front-side 148 and a rear-side 134. Silicon substrate 132 can be p-doped (for example having an electrical resistance of approximately 1 Ωcm). Charge carriers are generated within Silicon substrates 132 by means of light, which enters through the front-side 142 of the solar cell 104.

Inside the Silicon substrates 132, an emitter 130 is configured on the surface of the front-side 148. For example, the emitter 130 is a thin n-doped layer (layer thickness for example approximately 1 μm) having an electrical layer-resistance of approximately 50 Ω/sq to approximately 150 Ω/sq. The structure of a (pn) diode is realized by means of the n-doped emitter 130 and p-doped Silicon substrates 132.

Optionally, an antireflection coating 128 is also applied on the front-side 148 of the Silicon substrate 148. For example, this antireflection coating 128 can include Silicon nitride and can have a layer thickness of about 75 nm. The antireflection coating 128 lowers the proportion of reflected light, which enters through the front-side 142 of the solar cell 104.

A metallization (for example a Silver metallization) 126 is provided through the antireflection coating 128 and contacts the emitter 130. The metallization 126 (also referred to as “Front-side metallization” in the following) can be installed such that a highest possible electrical conductivity and a minimal shadow of the front-side 142 of the solar cell 104 against the incident light are available.

A dielectric layer structure 138 is disposed on the rear-side 134 of the Silicon substrate 132. For example, the dielectric layer structure 138 includes Silicon nitride (for example, of a layer thickness in the range of approximately 20 nm to approximately 200 nm, for example approximately 70 nm to approximately 170 nm) and essentially covers the rear-side 134 of the Silicon substrate 132 completely. In the dielectric layer structure 138, a plurality of through openings 158 extending through the dielectric layer structure 138 are provided, which expose partial areas of the rear-side surface of the Silicon substrate 132 (in other words, these partial areas are substantially free from material of the dielectric layer structure 138).

An Aluminum-containing metallization layer 136 is applied on the dielectric layer structure 138 by means of screen-printing (or for example, alternatively by means of Inkjet-printing). The Aluminum-containing metallization layer 136 covers the dielectric layer structure 138 substantially completely, except for example in a contact area 146. The contact area 146 includes a Silver-containing solder pad and is electrically connected to the Aluminum-containing metallization layer 136. The contact area 146 can be provided to enable soldering of a solar cell with other components (e.g. with other solar cells of the solar cell module 100).

A circular marking 140 schematically indicates the enlarged area of the solar cell 104; which is shown in the enlarged cross-sectional view 150 in FIG. 1C.

A cross-section of the solar cell 104 is schematically shown in the enlarged cross-sectional view 150. In various embodiments, the second area includes a plurality of second partial areas 154, wherein the Aluminum-containing metallization layer 136 in the second partial areas 154 has a layer thickness, for example—of approximately 25 μm. In various embodiments, the first area 152 has a layer thickness of the Aluminum-containing metallization layer 136 of approximately 10 μm. A circular through opening 158 with a radius of 20 μm extends through the dielectric layer structure 138. This enables the Aluminum-containing metallization layer 136 to make direct contact between the Silicon substrate 132 or to Al-BSF 162. Al-BSF 162 is shaped during the firing process. The first area 152 clearly constitutes an barrier for the diffusion of Silicon released during the firing process. The region of the through opening 160 marked in FIG. 1C by means of shading symbolizes a theoretical cylinder with the base area of the through opening 158. This region of the through opening 160 serves only for the theoretical explanation of the concentration of Silicon released during the firing process.

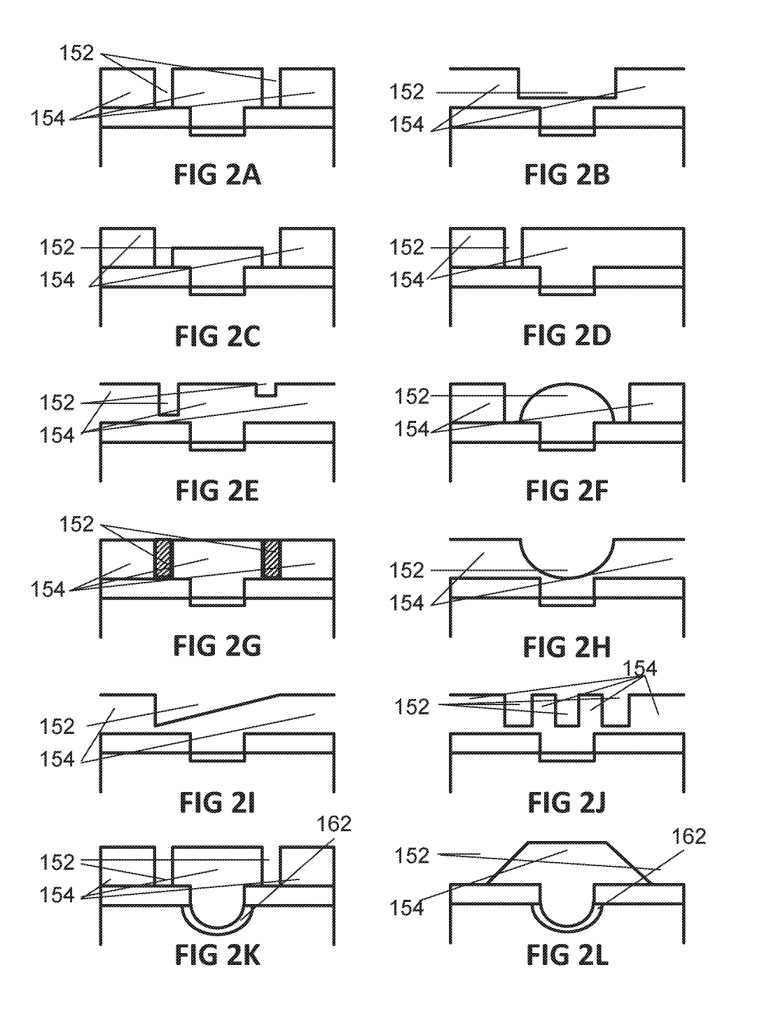

FIG. 2A to FIG. 2L show respectively a cross-section according to the enlarged cross-sectional view 150 of the solar cell 100 with different configurations of the first area 152 and the second area 154 or partial areas thereof. The configurations, particularly of the first area 152 or partial areas thereof, allow an adjustment of the electrical conductivity of the Aluminum-containing metallization layer and the adjustment of the barrier for the diffusion of Silicon released during the firing process. Since the figures are two-dimensional cross-sections, for example the connection of different areas or partial areas cannot be shown. Other geometrical shapes are possible in alternative exemplary embodiments. Thus, for example the second partial areas 154 shown in FIG. 2A to FIG. 2L can be represented two-dimensionally in the non-visible connection by means of a continuous (i.e. clearly electrically interconnected and thus at the same electrical potential) second area 154 and vice-versa. Analogously, the first area 152 can include a plurality of first partial areas 154.

FIG. 2A schematically shows an exemplary embodiment, as it was also shown in FIG. 1A within the scope of the solar cell 100 (or upside down according to FIG. 1A) and is used here as a comparison for the configurations according to FIG. 2B to FIG. 2L.

FIG. 2B schematically shows an exemplary embodiment, wherein in this case, the first area 152 has a constant reduced layer thickness above the through opening 158 with respect to the second area 154.

FIG. 2C schematically shows an exemplary embodiment, wherein the first area 152 has a partial area with reduced layer thickness and a partial area without Aluminum-containing metallization layer 136. Such an embodiment can seriously restrict the volume of the molten Aluminum for the diffusion of Silicon released during the firing process. The Aluminum-containing metallization layer 136 in the first area 152 and the Aluminum-containing metallization layer 136 in the second area 154 can be electrically interconnected (based on the two-dimensional representation not shown). In case, the Aluminum-containing metallization layer 136 in the first area 152 and the Aluminum-containing metallization layer 136 in the second area 154 are not electrically interconnected, an electrical connection can be made, for example by means of an additional contacting (not shown) during the solar cell module manufacture. Alternatively, another conductive layer can be applied, which electrically interconnects the areas.

FIG. 2D schematically shows an exemplary embodiment, wherein the first area 152 represents only a trench without Aluminum-containing metallization layer 136. According to composition of Al-Paste, the temperatures in the firing process or the duration of the firing process, such a diffusion barrier can be adequate for Silicon released during the firing process.

FIG. 2E schematically shows an exemplary embodiment similar to FIG. 2A, wherein first partial areas 152 can have different layer thicknesses. Such an asymmetrical configuration of the layer thicknesses can be useful to achieve an optimization of the electrical bulk conductivity of the metallization layer 136 and of the diffusion barrier for Silicon released during the firing process.

FIG. 2F schematically shows an exemplary embodiment similar to FIG. 2C. In order to optimize the volume of the molten Aluminum for Silicon released during the firing process, the first area can take most diverse shapes, as shown here.

FIG. 2G schematically shows another exemplary embodiment similar to FIG. 2A, wherein the first area 152 or partial area thereof is free from Aluminum-containing metallization layer 136. In this configuration, an insulating paste has been incorporated (for example by means of screen-printing) in the first partial area 152, which can electrically insulate as well as disconnect the volume of the different second partial areas 154.

FIG. 2H schematically shows another exemplary embodiment similar to FIG. 2G, wherein the Aluminum-containing metallization layer 136 in the first area 152 and the second area 154 are electrically interconnected. As explained according to FIG. 2F, the first area 152 can take any shape.

FIG. 2I schematically shows another embodiment, wherein the first area 152 is disposed asymmetrically above the through opening 158. As described with reference to FIG. 2E and FIG. 2D, an asymmetry can be used for optimization.

FIG. 2J schematically shows another exemplary embodiment, wherein alternatively different second partial areas 154 and first partial areas 152 are present. As in the case of asymmetrical first partial areas 152 (for example FIG. 2E), an optimization of the electrical resistance vis-à-vis the property as diffusion barrier for Silicon released during the firing process, can lead to different configurations of the first 152 and second area 154 or the partial areas thereof. A configuration as shown here can be additionally suitable for example to produce an area with larger surface, for example for a subsequent bonding during the solar cell module manufacture. Thus, such a configuration can produce several effects.

FIG. 2K schematically shows another embodiment similar to FIG. 2A, wherein the second partial areas 154 are “buried” through a cavity in Silicon substrate 132 (also “buried contact” in English). As shown schematically, Al-BSF 162 can also be affected accordingly the geometrical shape.

FIG. 2L schematically shows another exemplary embodiment with a “buried contact”, wherein there is only a second partial area 154 and a first partial area 152 in the surrounding of the through opening 158. Such an embodiment can severely restrict the volume of the molten Aluminum for the diffusion of Silicon released during the firing process. Aluminum-containing metallization layer 136 in the first partial area 152 and the Aluminum-containing metallization layer 136 in the second partial area 154 can be electrically interconnected (based on two-dimensional representation not shown). In case, Aluminum-containing metallization layer 136 in the first partial area 152 and Aluminum-containing metallization layer 136 in the second partial area 154 are not electrically interconnected, an electrical connection can be made, for example by means of an additional contacting (not shown) for example during the solar cell module manufacture. Alternatively, an additional second partial area (not represented) can electrically interconnect a plurality of second partial areas. As schematically shown, Al-BSF 162 can also be affected according to the geometrical shape.

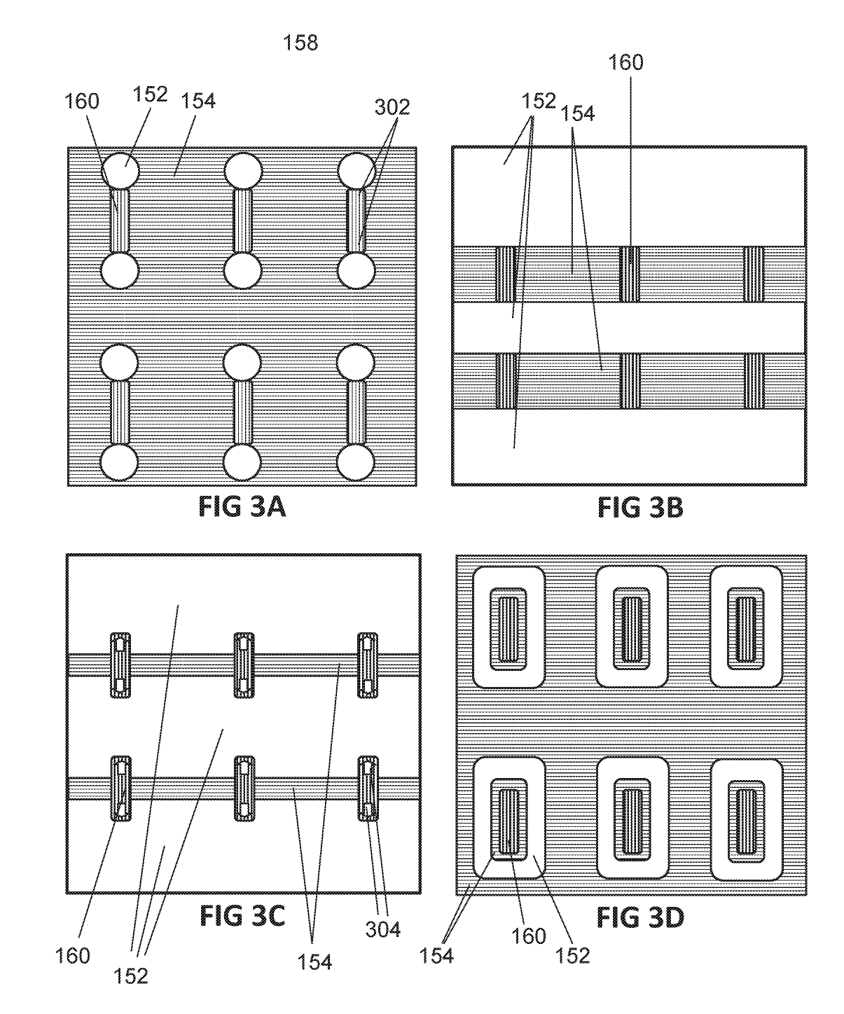

FIG. 3A to FIG. 3D respectively show a top-view on the rear-side of the solar cell. For the sake of clarity, only exemplary partial areas are provided with a reference numeral in the following figures. Different areas are distinguishable by means of the hatched markings.

FIG. 3A schematically shows an exemplary embodiment in the second area 154, which is marked with a horizontal hatching, almost the entire rear-side of the solar cell is filled out. The regions of the through openings 160, which are marked by a vertical hatching, are also part of the second area 154. The first area 152 or partial areas thereof have a reduced layer thickness with respect to the layer thickness of the second area 154 or are free from an Aluminum-containing metallization layer 136. The reference numerals 302 illustrate the position of the end areas of the trench-shaped regions of the through openings 160 in this example.

FIG. 3B schematically shows an exemplary embodiment, in which the first area 152 or partial areas thereof are free from an Aluminum-containing metallization layer 136. The second partial areas 154, which are marked by a horizontal hatching, cover the regions of the through openings 160.

FIG. 3C schematically shows an embodiment, in which the first area 152 or partial areas thereof are free from an Aluminum-containing metallization layer 136. The second partial areas 154 in stripes incompletely cover the regions of the through openings 160. However, as indicated here by the arrows 304, Al-paste can flow during the screen-printing and the region of the through opening 160 can be completely or partially filled out.

FIG. 3D schematically shows another embodiment in the first area 152 or partial areas thereof has a reduced layer thickness with respect to the second partial areas 154.

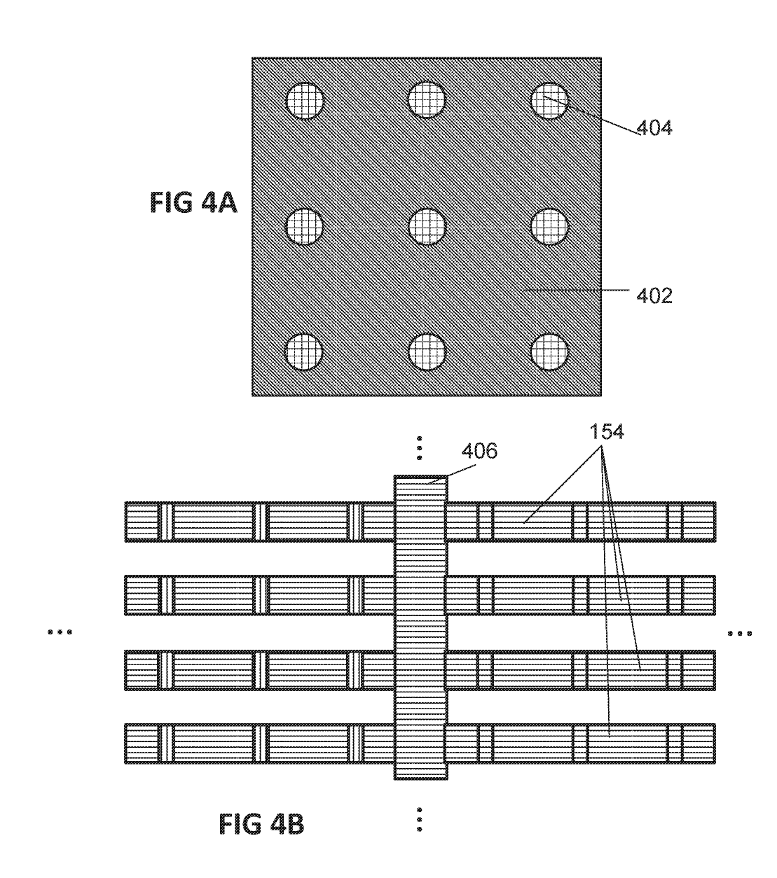

FIG. 4A schematically shows an embodiment of a screen layout for the screen-printing, for example—which can enable an Aluminum-containing metallization layer 136 according to FIG. 3A.

For the sake of clarity, only exemplary partial areas are provided with a reference numeral. Different areas are distinguishable by means of the marked hatching. The screen can include finely woven fabric 402, through which Al-paste is pressed by means of a scraper during the screen-printing. Moreover, the screen can be sealed by an emulsion layer at areas 404 on which a first area 152 should be realized on the rear-side of the solar cell 104, so that no Al-paste is printed on this area. Alternatively, the machine dimension, the fabric-thickness or the filament diameter of the fabric can be changed at these areas 404, so that a smaller amount of Al-paste is pressed and thereby, a lower layer thickness can be realized in the first area 152.

FIG. 4B schematically shows an exemplary embodiment according to FIG. 3B, wherein the second partial areas 154 are electrically connected by means of an (or in another example, also several) additional second partial areas 406.

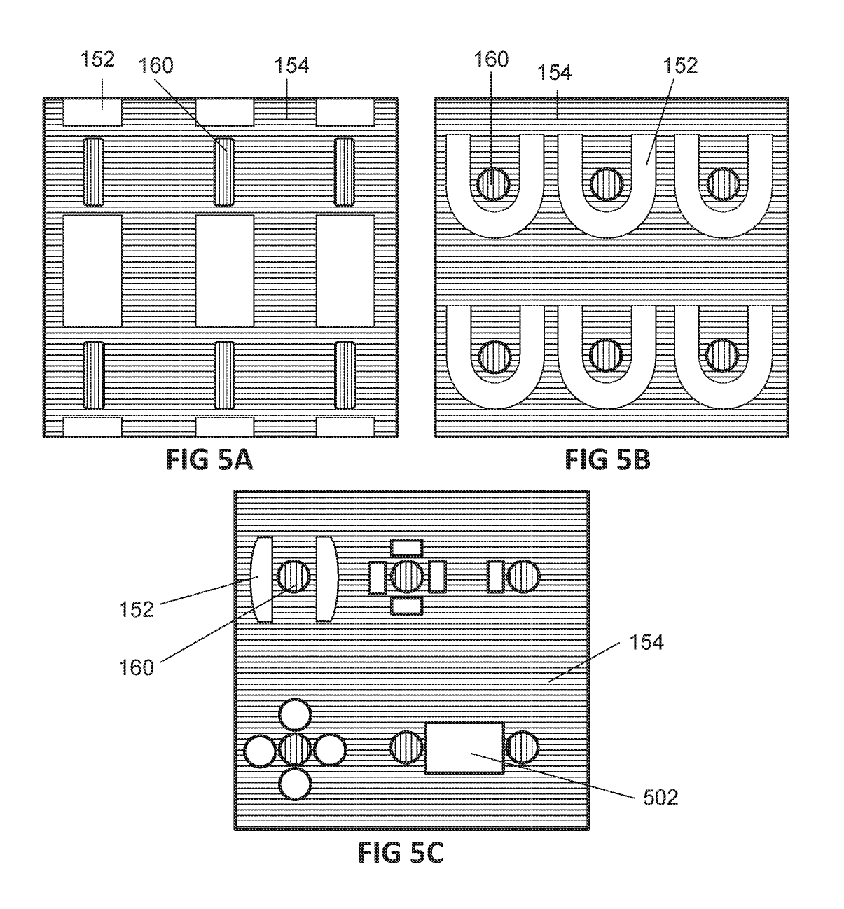

FIG. 5A to FIG. 5C respectively show a top-view on the rear-side of the solar cell 104. For the sake of clarity, only exemplary partial areas are provided with a reference numeral in the following figures. Different areas are distinguishable by means of the marked hatching. The hatching are marked in the same sense as the hatching of FIG. 3A to FIG. 3D.

FIG. 5A schematically shows an embodiment in the second area 154, which is marked by a horizontal hatching, fills almost the entire rear-side of the solar cell. The regions of the through openings 160, which are marked by a vertical hatching, are also part of the second area 154. The first area 152 or partial areas thereof have a reduced layer thickness with respect to the layer thickness of the second area 154 or are free from an Aluminum-containing metallization layer 136. In this embodiment, the partial areas of the first area 152 are disposed such that they are used as diffusion barrier of Silicon released for two regions of the through openings 160 during the firing process. Configurations not represented, in which a first area 152 or partial areas thereof serve as diffusion barrier in the above-mentioned sense, are used for several regions of the through openings 160, are obviously also possible.

FIG. 5B schematically shows another embodiment according to FIG. 5A.

FIG. 5C schematically shows another exemplary embodiment according to FIG. 5A. In order to save space in each region of the through opening 160, possible configurations of first areas 152 or partial areas thereof are marked. The first area 502 has a separate reference numeral in order to illustrate that this, according to FIG. 5A, is used as diffusion barrier for two (or several in other embodiments) regions of the through opening.

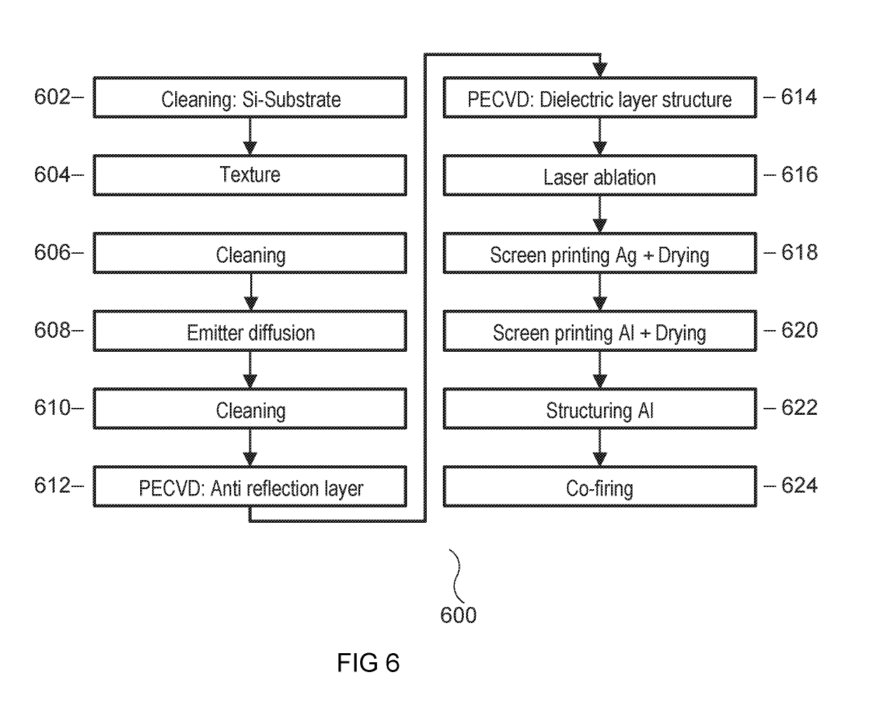

According to various embodiments, a process 600 is schematically represented in FIG. 6.

A Silicon substrate 132, for example monocrystalline, which is obtained from a Czochralski process or Float-zone process, or multi-crystalline, for example obtained from a Blockguss process (e.g. “Quasi-monocrystalline” also), which is p-doped by means of the crystallization process (about 2*1016 Boron atoms per cubic centimeter) is purged at 602. This purging can include, for example the function of saw-damage etching. This means for example that a surface layer of the Silicon substrate 132 is etched (about 10 μm per side) by means of a chemical solution (for example, diluted Potassium hydroxide KaOH). In addition, baths of diluted hydrochloric acid HCL are used for removing metallic impurities on the surface and/or in diluted hydrofluoric acid HF for removing oxide layers.

A texture is applied at 604. This means for example that the surface of the Silicon substrate 132 is roughened by means of a chemical solution (for example diluted Potassium hydroxide KaOH). This roughened surface lowers the reflection of light on the front-side of the Silicon substrate 132 or front-side of the solar cell 104.

Another purging is carried out at 606. This can be for example a cascade of water baths for removing the rest of the chemical solution, for producing the texture. In addition, baths are again carried out in diluted HCL and HF (as described according to 602).

At 608, an emitter 130 is inserted into Silicon substrate 132 through the front-side 148. This occurs in a diffusion pipe at about 750 to 850° C. in an atmosphere enriched with POCL3. Phosphorous in atmosphere diffuses by forming a so-called Phosphorous glass in Silicon substrate 132. For example, such an emitter 130 is made within Silicon substrate 132 having a layer thickness of less than 1 μm on the surface of the Silicon substrate 132. This (having about 1*1019 Phosphorous atoms/cm3 in the layer and about 1*1021 Phosphorous atoms/cm3 on the layer surface or on the surface of Silicon substrate 148) can have, for example an electrical resistance of approximately 50 Ω/sq to approximately 150 Ω/sq. The rear-side of Silicon substrate 134 can be protected, for example against the emitter diffusion by that two Silicon substrate abut each other (so-called “Back-to-Back” processing) during the diffusion.

At 610, the structure so obtained is purged again. In various embodiments, a bath in a diluted HF solution can remove the Phosphorous glass produced during the diffusion, and the edge insulation can be carried out.

At 612, an antireflection coating 128 is applied on the front-side 148 of Silicon substrates 132 by means of PECVD (Plasma Enhanced Chemical Vapour Deposition). This antireflection coating 128 can consist of, for example—Silicon nitride and can have a layer thickness of about 75 nm.

Subsequently at 614, a dielectric layer structure 138 (for example Silicon nitride having a layer thickness in the range of approximately 20 nm to approximately 200 nm, for example in the range of approximately 70 nm to approximately 170 nm) can be applied on the rear-side of the solar cell 104 by means of PECVD.

At 616, through openings 158 in the form of filled out circles having about 40 μm diameter are produced in the dielectric layer structure 138 by means of Laser ablation.

At 618, a Silver-metallization is applied in the form of lines on the front-side of the solar cell 104, i.e. on the antireflection coating 128 by means of screen-printing of Silver-paste and a drying process (for example a heat treatment at about 300° C. for a duration of about 180 seconds). In addition, Silver-paste is locally applied at few areas on the rear-side of the solar cell 104, i.e. on the dielectric layer structure 138 for forming the so-called solder-pads.

At 620, Al-paste is applied on the rear-side of the solar cell 104, i.e. on the dielectric layer structure 138 by means of screen-printing and a drying process (for example a heat treatment at about 300° C. for a duration of about 180 seconds). This Aluminum-containing metallization layer 136 is attached fully and with a constant layer thickness of about 25 μm on the dielectric layer structure 138 and thus, on the rear-side of the solar cell 104 (except on the few local areas with Silver-paste for making the solder pads).

At 622, a first area 152 in Aluminum-containing metallization layer 136 is produced by means of Laser ablation. For this purpose, circular depressions (first area 152 or partial areas) are formed in printed Aluminum-containing metallization layer 136 in a radius of about 20 μm around the circular through openings 160. These circular depressions have a depth of about 15 μm. The layer thickness of the Aluminum-containing metallization layer 136 is reduced to about 10 μm in this first area (in these circular depressions) by Laser ablation of Al-paste.

Subsequently, a firing process 624 is conducted at a temperature in the range of approximately 700° C. to approximately 900° C. Since Silver-paste and Aluminum-containing metallization layer 136 of the Al-paste are simultaneously “fired”, this process is also known as “Co-firing”. The heat treatment continues for about 10 seconds and subsequently, the solar cell 104 is cooled down. As described above, an Al-BSF 162 is made in the through openings 158 during the firing process and thus, an electrical contact between Silicon substrate 132 and Aluminum-containing metallization layer 136. Silver-paste penetrates through the antireflection coating 128 during the firing process and makes an electrical contact between Silver-metallization 126 and emitter 130.

The solar cell so obtained is electrically connected to other solar cells, for example by means of the solder pads 146 and Silver-metallization 126 via electrical connections, whereby a solar cell module can be manufactured.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell, comprising:
a silicon substrate with a front-side and a rear-side;
a dielectric layer structure on the rear-side of the silicon substrate, wherein the dielectric layer structure includes a plurality of through openings by means of which the rear-side of the silicon substrate is exposed;
a printed Aluminum-containing metallization layer on the dielectric layer structure on the rear-side of the silicon substrate and at least partially in the through openings for electrically contacting the rear-side of the silicon substrate;
wherein the Aluminum-containing metallization includes a lower layer thickness in a first area than in a second area, or the first area is free from the Aluminum-containing metallization;
wherein at least one through opening of the plurality of through openings is at least partially disposed in the first area or borders on the first area or has a distance from the first area of less than 500 μm.

2. The solar cell of claim 1,
wherein at least one through opening of the plurality of through openings is at least partially disposed in the first area or borders on the first area or has a distance from the first area of less than 200 μm.

3. The solar cell of claim 2,
wherein at least one through opening of the plurality of through openings is at least partially disposed in the first area or borders on the first area or has a distance from the first area of less than 50 μm.

4. The solar cell of claim 1,
wherein the at least one through opening of the plurality of through openings is configured in the shape of an elongated trench.

5. The solar cell of claim 1,
wherein the at least one through opening of the plurality of through openings is configured in the shape of a prism or a circular cylinder.

6. The solar cell of claim 1,
wherein the at least one through opening of the plurality of through openings has a length which is greater than the width thereof, so can also be square or elliptical;
wherein at least one end area of the at least one through opening is disposed in the first area or borders on the first area or has a distance from the first area of less than 500 μm.

7. The solar cell of claim 6,
wherein the at least one through opening of the plurality of through openings has a length which is greater than the width thereof, so can also be square or elliptical;
wherein at least one end area of the at least one through opening is disposed in the first area or borders on the first area or has a distance from the first area of less than 200 μm.

8. The solar cell of claim 7,
wherein the at least one through opening of the plurality of through openings has a length which is greater than the width thereof, so can also be square or elliptical;
wherein at least one end area of the at least one through opening is disposed in the first area or borders on the first area or has a distance from the first area of less than 50 μm.

9. The solar cell of claim 8,
wherein both end areas of the at least one through opening are disposed in the first area or border on the first area or have a distance from the first area of less than 500 μm.

10. The solar cell of claim 9,
wherein both end areas of the at least one through opening are disposed in the first area or border on the first area or have a distance from the first area of less than 200 μm.

11. The solar cell of claim 10,
wherein both end areas of the at least one through opening are disposed in the first area or border on the first area or have a distance from the first area of less than 50 μm.

12. The solar cell of claim 1,
wherein the first area includes a plurality of first partial areas;
wherein the second area includes a plurality of second partial areas;
wherein each of the second partial areas are at least partially configured in at least one through opening for electrically contacting the rear-side of silicon substrate;
wherein each of the second partial areas is at least partially disposed in a first partial area of the plurality of first partial areas.

13. The solar cell of claim 12,
wherein the second partial areas are substantially configured in strip-shape.

14. The solar cell of claim 13,
wherein the second partial areas are at least partially wider in one partial area of the through openings than outside the at least one partial area of the through openings.

15. The solar cell of claim 1,
wherein the layer thickness of the Aluminum-containing metallization layer is not constant in the first area.

16. The solar cell of claim 15,
wherein the dielectric layer structure includes one or more layers, wherein at least one of the plurality of layers is a dielectric layer.
